(19) United States
(12) Patent Application Publication
(10) Pub. No.: US 2017/0093382 A1
(43) Pub. Date: Mar. 30, 2017

(54) APPARATUS COMPRISING AN OSCILLATOR CIRCUIT, USE OF SUCH AN APPARATUS IN A RADIATION FIELD AS WELL AS METHOD FOR OPERATING SUCH AN APPARATUS IN A RADIATION FIELD

(71) Applicant: e-Gen GmbH, Berg (DE)

(72) Inventors: Hubertus-Christopher Voigt, Berg (DE); Gustav Hans Weber, Zurich (CH)

(73) Assignee: e-Gen GmbH, Berg (DE)

(21) Appl. No.: 15/272,202

(22) Filed: Sep. 21, 2016

Related U.S. Application Data
(60) Provisional application No. 62/234,577, filed on Sep. 29, 2015.

(51) Int. Cl. H03K 3/42; H02S 40/30

(52) U.S. Cl. CPC H03K 3/42; H02S 40/30

(57) ABSTRACT

An apparatus with an oscillating circuit, which is excitable by means of an alternating signal source. The oscillating circuit includes a non-linear circuit element. The apparatus is designed so that the non-linear circuit element is operable in a non-linear operating range and with a frequency above its limiting frequency.

### CROSS-REFERENCE TO RELATED APPLICATIONS

This application claims the benefit of priority to U.S. Provisional Application No. 62/234,577, filed on Sep. 29, 2015, which was filed in a language other than English. An English translation of the German language provisional application and a statement that the translation is accurate were both filed in U.S. Provisional Application No. 62/234,577 on Sep. 14, 2016. All applications are incorporated by reference in their entirety for all purposes.

### FIELD OF THE INVENTION

The present invention concerns an apparatus with oscillator circuit as well as the use of such an apparatus in an artificially generated or naturally occurring radiation field. Furthermore, the present invention concerns a method for operating such an apparatus in an artificially generated or naturally occurring radiation field.

### BACKGROUND OF THE INVENTION

There is a demand for devices or circuits which are suitable for (signal-)amplification, Amplifier circuits are typical examples which are designed in order to transform a weak electrical signal into a stronger electrical signal. But there are also numerous examples of amplifier circuits which, for instance, are transforming an input quantity in a first regime (e.g. an acoustic wave) into an output quantity in another regime (e.g. an analog electrical signal). Such circuits usually comprise some kind of converter (e.g. a solar element) being designed in order to absorb or to receive the input quantity of the first regime to transform it into the output quantity of the other regime.

There are numerous different solar elements which are designed for transforming solar energy into electrical power. Solar elements are operated so as to deliver a direct current. The respective direct current in solar elements is always flowing in the same direction. If the solar element is grid-coupled, the direct current generated in the solar element is transformed by means of a rectifier into an alternating current being fed into the grid. In isolated facilities, however, the direct current is typically used right away. A solar element has a characteristic non-linear voltage-current curve. The optimum operating point of a solar element is defined by the provision of a voltage and a current and determines the maximum power of the element. During normal operation, a special control is keeping the solar element in the region of the respective optimum operating point when the solar radiation is changing in order to be able to draw the maximum power. If operated at the operating point, the solar element has a linear behavior, the current and voltage are constant.

Despite all the development efforts of the recent years, the efficiency of these solar elements has only been improved marginally.

The following statements, which are general, can be postulated:
The quantum yield is smaller than one;
The recombination ratio is greater than zero;
The internal resistance is greater than zero.

The quantum yield, the so-called recombination mechanisms in the space-charge region (where charge carriers, being generated by the radiation, are “lost” because of recombination) and at boundary layers, as well as the existing ohmic internal resistance are limiting the efficiency of a solar cell. The quantum yield is depending on the number of electrons which are being transported in the space-charge region of a solar cell into the conduction band per number of impinging photons. Each light quantum in case of an ideal solar cell, which has an energy larger than the characteristic energy gap (band gap) of the semiconductor, is contributing towards the photo current of the solar cell. In practice, this value (called quantum yield) is always smaller than one.

There is a great demand for improving the efficiency of solar elements. In this context, the search for new possibilities are in the foreground which facilitate the optimization of the transformation of impinging light into electrical power. The point is to improve the quantum yield as well as to reduce the recombination rate and the internal resistance.

### SUMMARY OF THE INVENTION

In accordance with the invention, an oscillating system is preferably provided as an apparatus which can be temporarily or permanently triggered (e.g. by means of a control signal) by means of an alternating signal source or which is designed as self-oscillator.

In accordance with the invention an apparatus comprising an oscillating system is preferably provided which is designed as self-oscillator.

The oscillating system or the oscillating circuit are preferably comprising at least one complex-valued impedance which, for instance, is representing a capacity and an inductivity, in the corresponding electric equivalent circuit. The oscillating system or the oscillating circuit are characterized in that they comprise at least one non-linear circuit element, the influence of which on the oscillating circuit being caused by the application or coupling of an external radiation field into or by the transformation of an external radiation field.

Preferably, a solar element is used as a non-linear circuit element, whereby this solar element preferably is part of the oscillating system. The already mentioned oscillating circuit is a particular embodiment of the oscillating system.

An oscillating system may comprise one or more electric oscillating circuits. Preferably, all oscillating circuits are electric circuits being able to oscillate in resonance.

The term “solar element” is herein used a generic term for different light sensitive apparatuses. The term “solar element” thus includes, amongst others:
Individual light active circuits (such as, for instance, a light sensitive diode or a solar cell);
Multiple light active circuits (such as, for instance, a connection of light sensitive diodes and/or a solar cells).
   Amongst others, solar modules, panels or facilities are summarized by the term “solar element”. The term “solar element” is also not meant to be understood in a limiting fashion as far as the frequency of the light is concerned. This means that the “solar element” is not only an element designed for being exposed to natural sun light. The “solar element” can also be designed for special ranges of the natural or artificial light spectrum.

The term “solar element” also includes different light sensitive apparatuses, which are one part (e.g. on a carrier plate), monolithic (e.g. on a wafer), multi-part (e.g. on separate carrier plates) or multi-piece (e.g. on multiple wafers).

The term “solar element” also includes mono and poly crystalline Si-solar cells, solar cells with amorphous structure, thin layer solutions and large area diode structures with a light sensitive barrier layer.

The term “solar element” also includes inorganic semiconductor solar elements, solar elements on graphite basis, organic solar elements and hybrid solar elements (a solar cell which comprises organic and inorganic components).

The invention is suited for use in isolated facilities as well as in grid connected facilities.

The invention is based on basic quantum physics calculations and precise calorimetric measurements of different solar elements, which were preferably operated in the non-linear region.

This did, in particular, concern analytic calculations and experimental, highly precise calorimetric measurements of oscillating systems and the heat formation. In particular, the oscillating behavior of solar elements has been the subject of basic investigations and the results of the investigations has been scaled with the results of the quantum physics calculations.

It is known that immediate recombination effects occur in solar elements. The recombination effects as well as the material oscillations, which are transformed in heat, contribute to the reduction of the efficiency.

The invention directly interacts with the electronic circuitry, respectively with the operation of the solar elements.

In order to be able to employ a solar element of the invention in the non-linear region, it is preferably not operated in a readily defined operating point. In order to be able to put to use the non-linear properties, preferably degrees of freedom are admitted by a respective electric circuitry.

Preferably, the solar element is employed as part of an oscillating system or it is connected to an oscillating system, whereby it is exposed to alternating parameters.

Preferably, the inventive apparatus is providing alternating currents and/or direct currents, which can be tapped into or processed further or consumed.

Preferably, the solar element is included in an electric oscillating system so that it is being operated in a non-linear operating region of a characteristic field instead of an operating point of the voltage-current-curve. The non-linear operating region of the characteristic field is determined by various environmental variables and influencing parameters.

Preferably, the environmental variables and influencing parameters are adjusted or predefined for the various embodiments so that the solar element oscillates and operates non-linearly.

Preferably, the solar element is included in an electric oscillating system (preferably being designed as oscillating circuit) which comprises at least one complex-valued impedance with a resistor and/or capacity and/or inductivity, for instance. Due to this connection or link of the non-linear solar element with at least one complex impedance, a circuit results which is able to oscillate (called oscillating system herein). When operating this oscillating system, permanently changing degrees of freedom are thus resulting which are heading towards the desired non-linear behavior of the solar element. A complex relation between the input quantities (illumination of the solar element) and the output quantities of the solar element are resulting during its operation due to internal oscillations of the solar element.

The already mentioned complex-valued impedance, respectively at least one inductivity or capacity of the impendence, can be part of the non-linear circuit element/solar element and/or it can be realized by other elements, circuit groups or portions of the apparatus.

The term “non-linearity”, which is used herein, is to be understood as mathematical-physical phenomenon which, if expressed in general, the relation between an input signal or an input quantity and an output signal or an output quantity is non-linear.

Unlike in previous circuits, the solar element is preferably intentionally operated and controlled in the non-linear region. The solar element is preferably employed as non-linear circuit element.

The oscillating circuit (if present) is preferably designed so that the non-linear circuit element/solar element is operated in a non-linear region. That is, the oscillating circuit are designed so that the non-linear circuit element/solar element are operable in its non-linear region.

The non-linear circuit element/solar element can be designed so that it is influenceable by a non-contact applied or an external radiation field coupled in.

The non-linear circuit element/solar element is designed so that in operation mode (i.e. if the oscillating system or the oscillating circuit are operating) the internal field in the material of the non-linear circuit element/solar element is being modulated. The internal field of the non-linear circuit element/solar element can be influenced by the external radiation field.

Preferably, there is or results a field in the material of the non-linear circuit element/solar element which can be modulated by electric stimulation—preferably by stimulation by means of signaling—of the non-linear circuit element/solar element.

By the operation of the non-linear circuit element/solar element in an oscillating system (e.g. in an oscillating circuit) a space and/or time variable electric field is resulting in the material of the non-linear circuit element/solar element.

Preferably, special processes are stimulated in the material of the non-linear circuit element/solar element which, depending on the strength of the field, may contribute to the modulation of a carrier depleted (intermediate-) zone in the material of the non-linear circuit element/solar element. This (intermediate-) zone is herein called space-charge region.

Preferably, there is or results a carrier depleted (intermediate-) zone in the material of the non-linear circuit element/solar element which separates a zone with excess electrons and a zone with excess holes. This statement primarily holds in the static state respectively as long as the oscillating system (e.g. the oscillating circuit) is not being operated. The electrons (negatively charged particles) and holes (positively charged “particles”) are herein generally called charge carriers.

It is known that there are free charge carriers in the material of the non-linear circuit element/solar element or that these are generated during operation. Preferably, there are free charge carriers which are mobile if the non-linear circuit element/solar element is being modulated (e.g. by the application of an alternating voltage when operating the oscillating system).

The non-linear circuit element/solar element can have an internal structure which comprises two different material regions or material layers and a material transition between these two different material regions or layers. In this case, the material transition serves as charge depleted intermediate zone and the two different material regions may contain electrons in the one region and holes in the other region.

The two different material regions or layers may comprise differently doped semiconductor materials.

The oscillating system (e.g. having the form of an oscillating circuit) preferably comprises at least one solar element as non-linear circuit elements and the oscillating system comprises at least a capacity and an inductivity in the respective electric equivalent circuit.

Preferably, the oscillating system can be influenced by the application or coupling in of the external radiation field in the form of light or by the transformation, respectively, by the utilization of this external radiation field.

The electrical oscillating system is preferably designed or constructed so that the solar element together with the other elements of the oscillating system show a self-oscillating characteristic. This self-oscillating characteristic is characterized by a characteristic natural resonance frequency which is essentially determined by the elements/components of the oscillating system. Furthermore, the self-oscillation is supplied with energy being provided by the solar element due to the transformation of light. In addition, the self-oscillating characteristic shows a damping due to losses. Such electrical oscillating systems are herein referred to as self-oscillators since they can oscillate freely at least temporarily.

Preferably, the solar element is exposed to an alternating signal because of the self-oscillation of the oscillating system, that is modulated currents are flowing through the solar element. Furthermore, the solar element itself is providing the necessary energy for maintaining the oscillation.

Preferably, the invention comprises an oscillating system (preferably an electrical oscillator or several electrical oscillators, serving as oscillating system), Other than a conventional oscillating system, it is preferably being controlled by the periodic or quasi periodic opening and closing of a switching element. The respective control signal has a switching frequency which is equal to or smaller than the characteristic natural resonance frequency of the oscillating system. Preferably, the switching frequency is in a range from zero to 10 MHz, but in case of diode-based embodiments is can even be higher.

Preferably, a pulsed electrical oscillator serves as oscillating system which at least temporarily is oscillating freely.

Preferably, the electrical oscillating system is switched or stimulated by a control signal which is synchronized with the self-oscillating behavior in order for the switching procedure not to disturb or suppress the self-oscillating behavior, but to constructively stimulate and/or maintain it.

Furthermore, the inventive oscillating system shows a different behavior than a conventional oscillating system due to the presence of a solar element. In addition, the solar element in the inventive electric circuitry shows a non-linear behavior which in turn has an influence on the oscillating properties of the oscillating system.

In accordance with the invention, an apparatus is employed as part of or in the area of a so-called power circuit of the oscillating system in order to be able to operate the oscillating system with the already-mentioned control signal. The oscillating system with solar element shows an self-oscillating behavior in the respective switching mode which decays because of losses of the power circuit (called damping).

Preferably, it is about oscillating systems being designed or operated as oscillating circuits, as already mentioned. In these self-oscillators energize, which is required for the oscillation, it is essentially drawn out of the non-linear circuit element (herein preferably a solar element illuminated with light).

The self-oscillators of the invention preferably require a control signal from time time for activating a switch in order to he able to draw/obtain electrical power out of the oscillating circuit.

The self-oscillators of the invention preferably require a continuous or periodic energy supply as damping compensation. This energy supply can be synchronized with the self-oscillation of the oscillating circuit by means of a control signal.

Preferably, in a self-sustaining embodiment of the invention, the control signal can be taken out of the power circuit. In a non-self-sustaining embodiment, however, the control signal is preferably being provided externally (called externally modulated oscillating circuit having a self-oscillating behavior).

In a self-oscillator, preferably no or only a negligible energy amount is fed by the control signal into the oscillating circuit.

Preferably, the control signal is applied to a switching element of the power circuit so that the control signal couples none or only a small amount of energy into the power circuit,

In embodiments with externally switched oscillating systems, the switching of the oscillating system is preferably carried out from outside of the power circuit. For this purpose, the apparatus may comprise a control circuit which can be technically coupled with the power circuit by circuitry (preferably galvanically or optically decoupled).

Preferably, the oscillating system comprises at least one solar element and at least on inductivity. The oscillating behavior of such an oscillating system can he subdivided into the following steps or sequences. This subdivision is only done for a better illustration of the correlations:
A. The inductivity is charged by a current being provided by the illuminated solar element.
B. During this charging process, a damped self-oscillation of the oscillating system occurs.
C. If the inductivity is charged sufficiently, then a temporary interruption of the charging process takes place.
D. Due to this, a discharge of the inductivity occurs.

These steps or this sequence can be released/influenced or triggered by the application or removal of a control signal.

Preferably, the oscillating system can he operated or used so that it shows the mentioned self-oscillating behavior at least temporarily.

In accordance with the invention, the power circuit (if present) is preferably designed in order to make available electric power at a tap (e.g. two nodes, poles or contacts) so that electric energy can be drawn from the solar element, if illuminated. The drawing out of electric power is preferably not done directly from the solar element but the power is partly stored (intermediately) in the oscillating system and taken out only then.

For instance a load, which is to be supplied by solar power, can be connected to the tap or an energy storage (accumulator or super cap) can be connected in order to (intermediately) store the electric power.

For instance, a controller or a rectifier or another load can be connected to the tap.

Preferably, the power circuit is providing an oscillating signal (called alternating current signal) at a tap (e.g. two nodes, poles or contacts), as compared to conventional solar element which nowadays are providing a direct current signal only. Additionally or alternatively, an oscillating system of the invention might supply a direct current signal.

A rectifier can be hooked up to an optional tap in order to carry out a transformation of the oscillating output signal (alternating current signal) into a direct current.

A modified rectifier can be hooked up to an optional tap in order to generate a desired alternating current signal (e.g. 220V at 50 Hz) out of the oscillating output signal.

The power circuit preferably draws electric energy out of the solar element illuminated by light.

Preferably, coils with core are employed as inductivities.

The oscillating system is preferably galvanically or optically (e.g. by means of an opto coupler) separated from a control circuitry (also called control circuit).

The control circuit, if present, may comprise a control signal emitter (also called generator) which switches the power circuit by means of periodic or quasi-periodic control signals, respectively triggers the self-oscillation of the power circuit.

The switching frequency of the periodic or quasi-periodic control signal is preferably smaller that the self-oscillating frequency at which the oscillating system, including the solar element, is oscillating. Preferably, the switching frequency is an integral part of the self-frequency.

The non-linearly operated solar elements have a device specific lower limiting frequency. The solar element virtually shows a typical diode behavior below this limiting frequency, if stimulated above this device specific lower limiting frequency, the solar element starts to guide through alternating current signals. The oscillating system is thus preferably operated at an operating frequency which is above the device specific lower limiting frequency.

In order to reach the region of non-linear behavior, the operating frequency should be above the device specific lower limiting frequency and a device specific minimum amplitude of the oscillation is used. The saturation of the signal which is oscillating at the operating frequency is thus elected so that the oscillation of the non-linearly operated solar element has a maximum oscillation amplitude which is at least equal to or larger than the difference of open circuit voltage and medium operation voltage of the solar element. The saturation of the signal which is oscillating at the operating frequency is to be chosen so that the maximum amplitude of the current signal corresponds to at least twice the medium current running through the non-linear circuit element.

Different operating points may exist above the lower limiting frequency which altogether are laying in one or several operating regions of the characteristic field of the solar element. The operating region can be determined empirically, for instance. The switching frequency of the control signal should oscillate in-phase with the actual operating frequency of the non-linear solar element.

Preferably, the lower limiting frequency is in the range between 5 and 20 kHz, and particularly advantageously in the range between 6 and 18 kHz. Especially preferred is a range between 7 and 15 kHz. However, the lower limiting frequency depends on the actual implementation of the embodiment and thus can also be in other ranges.

Embodiments should preferably oscillate at an operation frequency which is above this lower limiting frequency.

The upper limit preferably results from the self-oscillating frequency of the oscillating system actually used. In the case of oscillator circuits with solar element, this self-oscillating frequency is in the low megahertz region. The operation frequency at which the embodiments of the invention oscillate are preferably laying in the range below 10 MHz and preferably in the range below 8 MHz. Especially preferred the operation frequency of embodying with solar element are in a range below 2 MHz.

Preferably, the upper limit of the switching frequency is defined by the self-oscillating frequency of the oscillating system. The self-oscillating frequency is depending on the choice of the devices (for instance the inductivity).

Preferably, the upper limit of the switching frequency is less than or equal to the self-oscillating frequency of the oscillating system.

Preferably, the power circuit of the oscillating system is supplied with energy from the oscillating, light illuminated solar element. In most cases, there is thus no need for an external energy supply for the power circuit of the oscillating system.

Preferably, the power circuit of the oscillating system is designed as circuit which is able to oscillate so that it shows a self-oscillating behavior and that it essentially draws its energy from the light illuminated solar element.

Preferably, there are free charge carriers in the material of the solar element which are mobile. If the solar element is operated as part of an oscillating circuit (e.g. by applying a control signal) fast charge carriers movement processes are triggered.

The solar element may comprise an inner structure that comprises two different material regions or material layers and a material transition between these two different material regions or layers. The material transition in this case serves as charge depleted (intermediate) zone and the two different material regions might comprise electrons in the one region and holes in the other region. The two different material regions or layers may comprises differently doped semiconductor materials. An intrinsic field occurs due to the charge separation in the solar element. The invention uses this intrinsic field amongst other things by modulation of the oscillating circuit.

A solar element can be used in a special new operation mode where power in the form of current can be obtained from the apparatus of the invention, while the solar element is oscillating at an operation frequency or is showing a self-oscillating behavior with a self-oscillating frequency, preferably in a resonance region.

The solar element does not have to be operated/used in the resonance region in all embodiments. It can also be stimulated to oscillate at the mentioned operation frequency.

In order to be able to operate a solar element oscillatingly, it is preferably a component of the electrical oscillating system.

The electrical oscillating behavior of the solar element as part of an oscillating system adapts itself to the dynamics of the charge carrier pairs inside the solar element. The dynamics of the charge carrier pairs is primarily determined by the generation rate, mobility and recombination rate as well as by the total impedance of the oscillating system.

Preferably, the solar element is operated/used as component of an oscillating circuit so that the oscillation of the solar element and the whole oscillating system is fed by photovoltaic effect. The energy of the illuminated solar element in this case preferably serves for the charging of the inductivity(ies) of the oscillating circuit.

Preferably, the solar element is operated/used as component of an oscillating circuit so that the inductivity(ies) serve(s) as intermediate energy buffer for energy provided by the illuminated solar element.

A method for operating an electrical oscillating system with solar element preferably comprises the following steps:
Exposing or introducing the non-linear circuit element (here in the form of a solar element) to a radiation field (here in the form of light);
Stimulating an oscillating behavior of the oscillating system whereby the solar element and the oscillating system are oscillating at an operation frequency (preferably electrically free and in resonance);
Making available a direct current signal and/or an alternating current signal at the oscillating system or the solar element.

The term “making available” is in the context of an alternating current signal and/or direct current signal used in order to paraphrase the extracting, taking off, taping, providing, passing on or delivering of electrical energy.

Preferably only the direct current power (all of it or part of it) or only the alternating current power (all of it or part of it) are drawn out of the oscillating system, or the direct current power (all of it or part of it) as well as the alternating current power (all of it or part of it) are drawn out of the oscillating system.

Preferably, the stimulation of the self-oscillating behavior of the oscillating system is done so that a modulation of the solar element and of the electric field inside the solar element are effected.

If the solar element is used/operated in accordance with the invention one or more of the following advantageous properties is present:
a. It comes to an increase of the free charge carriers in the solar element;
b. The quantum yield of the solar element is increased;
c. The internal resistance of the solar element is reduced (i.e. the inner ohmic losses are reduced).

Preferably, the solar element is operated/used as a component of an oscillating circuit so that the self-frequency is an integer multitude of the switching frequency of the control signal. The extraction of energy can be done in phase with the self-oscillation of the oscillating circuit.

Further details and advantages of the invention will be described in the following by means of embodiments and with reference to the drawings.

### BRIEF DESCRIPTION OF THE DRAWINGS

FIG. 1A shows a simplified equivalent circuit of a solar element of the invention;

FIG. 1B shows a more accurate equivalent circuit of a solar element of the invention;

FIG. 1C shows a concentrated equivalent circuit of a solar element of the invention;

FIG. 1D shows the circuit symbol of a single solar cell, which can be part of a solar element of the invention;

FIG. 2 shows an equivalent circuit of a first apparatus of the invention;

FIG. 3 shows an equivalent circuit of a second apparatus of the invention;

FIG. 4 shows an equivalent circuit of a third apparatus of the invention;

FIG. 5 shows an equivalent circuit of a fourth apparatus of the invention;

FIG. 6 shows an equivalent circuit of a fifth apparatus of the invention;

FIG. 7 shows an equivalent circuit of a sixth apparatus of the invention;

FIG. 8 shows a voltage-current diagram of an exemplary switching signal of the invention;

FIG. 9 shows a connection scheme of an embodiment which is based on the principle of the second apparatus of the invention;

FIG. 10 shows a connection scheme of a further embodiment, which is based on the principle of FIG. 9.

### DETAILED DESCRIPTION OF THE INVENTION

An apparatus is herein called a circuit element which can be part of an electrical operating circuit. It does not necessarily have to be a discrete circuit element. Generally, a discrete circuit is an electrical circuit element in an own housing with its own outer ports (e.g. in the form of metal contacts). However, herein, the term “discrete circuit” is to be understood to be broader. A discrete circuit concerns a functional unit. Pursuant to the scope of the invention, a discrete circuit is a functional unit being provided with outer ports or to which outer ports (e.g., at couple pads) can be attached. There does not necessarily have to be a housing.

The discrete circuit of the invention, for instance, can be assembled out of several functional units of equal or different type.

If, for instance, an oscillating circuit with one capacity and one inductivity is referred to, then the capacity as well as the inductivity can be formed out of several partial elements and/or subcomponents and/or areas (e.g. the cables, feed lines, conductive paths) of the apparatus. Generally, it is thus also referred to as complex value impedance Z. The impedance Z might comprise at least one ohmic resistance (e.g. R, R1 or R2) and/or at least one capacity (e.g. C, C1 or C2) and/or at least one inductivity (e.g. L, L1 or L2). The behavior of the impedance Z in the oscillating circuit can be described by a complex value function. The impedance Z is here to be regarded as a passive two-terminal. The complex value impedance Z, and at least one inductivity or capacity of the complex value impedance can be part of the non-linear circuit element 10 (e.g., of the solar element).

In the following, an external radiation field EF (in most cases sun light and/or artificial light) is generally referred to. This term subsumes radiation fields of electro-magnetic nature.

The non-linear behavior of circuit element is generally undesired. However, the non-linearity is deliberately used in accordance with the invention. Making generalizations, the following can be postulated. At least one of the following values of the non-linear circuit element 10 is variable: Resistance (Rn1) inductivity (Ln1) capacity (Cn1). If presented in the form of an equation, the following applies (the indexes “nl” implicate that in this equation the (inherent) properties of the non-linear circuit element 10 are concerned):

Rn1=f(I) and/or Ln1=f(I) and/or Cn1=f(q), wherein I stands for the current and q for the charge carrier density.

Up to a point which is, for instance, definable by measurement, the non-linear circuit element 10 typically has a linear behavior in a range of defined value (or strength) and representation of the shape of the input signal. Thereafter, the behavior is going to be non-linear. The non-linear circuit element 10 is deliberately operated in the non-linear region.

Preferably, the non-linear circuit element 10 is operated above a lower limiting frequency in order to bring the non-linear circuit element 10 into a suitable oscillating behavior.

Preferably, a discrete circuit element is employed as non-linear circuit element 10. Such non-linear circuit elements 10 can generally be described by one or more characteristic curves or by one or more (multi-dimensional) characteristic fields. There is no linear relationship in the operation range of the invention, for instance, between a voltage applied to the input side of the non-linear circuit element 10 and a current to be taken out at the output side of the non-linear circuit element 10.

The oscillating system (e.g., in the form of an electrical oscillating circuit) may comprise at least one solar element as a non-linear circuit element 10. By the application of light as external field EF, this solar element 10.1 is able to couple or feed energy from the outside into the electrical oscillating system. In case of continuous light irradiation, energy can be supplied to the electrical oscillating system periodically or continuously.

Preferably, a solar element 10.1 is used as non-linear circuit element 10 which is providing electric energy when light is impinging. A solar element 10.1 can be represented by a current source in the equivalent circuit, which is transforming the impinging light into a photo current.

To some extent, reference is made herein to equivalent circuit diagrams in order to be able to describe the actual circuit of the invention by means of idealized electronic circuit elements. The physical function of the equivalent circuit diagrams corresponds to those of the actual circuits/apparatus 100 of the invention.

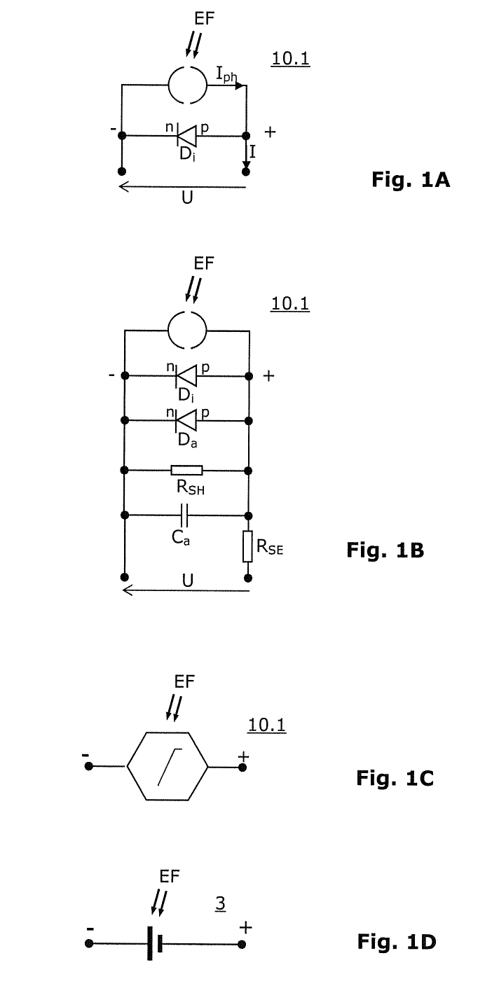

The function of such a solar element 10.1 can, for instance, be based on the photovoltaic principle. A solar element 10.1 of the invention might for instance comprise one or more solar modules, but the solar element 10.1 might as well be a single solar cell 3 (see, for instance, FIG. 1D) or several solar cells 3.

The invention can be used in all solar elements 10.1 which are operated as current sources in a so-called power circuit which is able to oscillate.

Herein, a power circuit which is able to oscillate is the part of an apparatus 100 that is designed for generating electric power. To some extent, large currents can flow in the power circuit and high voltages can occur. The conductive path of the power circuit thus has to be dimensioned accordingly.

FIG. 1A shows a simplified equivalent circuit diagram of an illuminated solar element 10.1 in conducting direction (for the sake of simplicity a one-diode model is used here). The equivalent circuit diagram comprises a parallel circuit of a current source (this current source is delivering a photo current Iph if light as external field EF impinges on the solar element 10.1) and a diode Di. This diode Di represents the p-n-transition of the solar element 10.1.

A voltage U can be taken from the parallel circuit. The voltage U corresponds to the open circuit voltage of the solar element 10.1 if there is no load at the parallel circuit. If, for instance, load resistor is arranged in parallel to the diode Di, then a current I is flowing through this load.

A solar cell 3, which, for instance, can be part of the solar element 10.1 of various embodiments of the invention, in practice has in addition to the one diode Di, which is shown in the equivalent circuit of the one-diode model of FIG. 1A, further concentrated elements which have to be taken into consideration for a more precise calculation. Typically, there is thus a second diode Da inserted in parallel to the first diode Di (these two diodes have different cut-off currents and temperature voltages). Furthermore, resistors RSH, RSE and an additional capacity Ca (e.g, for contacts and the space charge zone of the solar cell 3) have to be taken into consideration. A respective equivalent circuit diagram is shown in FIG. 1B.

It is the objective of all equivalent circuits and models with concentrated elements mentioned to simulate the physical processes in a solar cell with real technical circuit elements. The better one defines the equivalent circuit and its concentrated elements, the better the calculative approximation is.

If a solar cell 3 is not illuminated (called dark situation), the current source in the equivalent circuit is omitted. The unlighted solar cell 3 is a semiconductor diode letting flow a current from the p to the n-side if the voltage U across the diode is directed from p to n.

In FIG. 1C, the equivalent circuit of the solar element 10.1, is simplified as circuit block. To some extent, this concentrated representation is used in the subsequent figures, whereby no conclusions regarding the real construction of the solar element 10.1 regarding its constituents/components is to be drawn from this concentrated representation.

FIG. 1D shows the real circuit symbol of a single solar cell 3 which can be part of a solar element 10.1 of the invention. For practical applications of the invention, typically several solar cells 3 are interconnected to form one solar element 10.1., in order to be able to obtain the desired electric power. The solar element 10.1 of the invention may for instance comprise
A serial connection of two or more than two solar cells 3,
A parallel connection of two or more than two solar cells 3,
Or a combination solar cells 3 connected in parallel and in series.

In order to be able to provide voltages at a tap 4 of the apparatus 100 which are practically useful, several solar cells 3 might be connected in series,

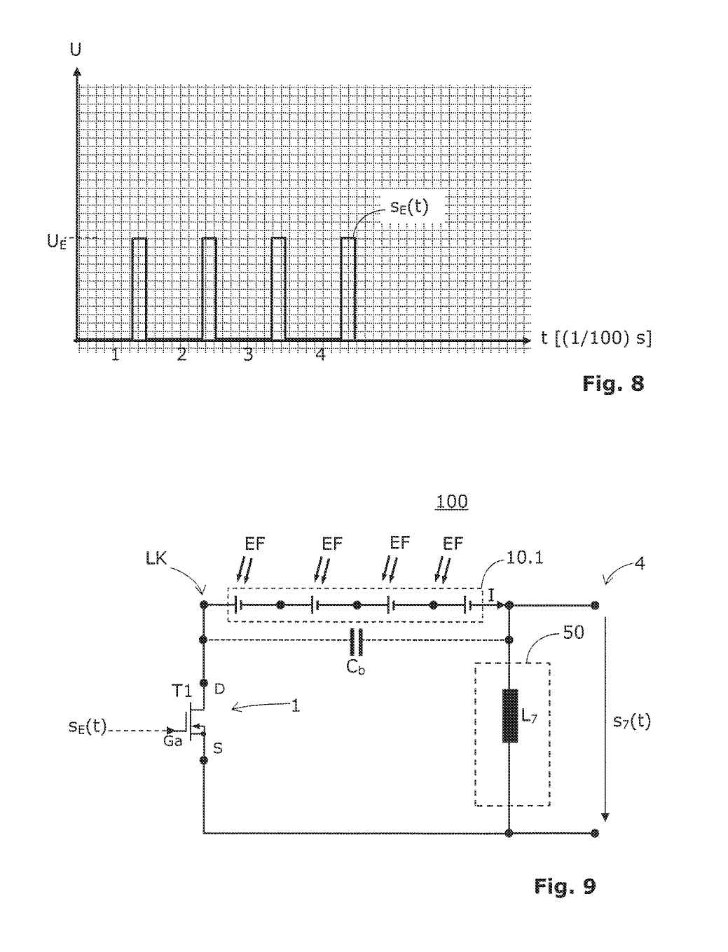

The apparatus 100 of the invention can be stimulated by means of an alternating signal source G. Preferably, the apparatus 100 thus comprises taps 1.1, 1.2 or coupling areas for applying or coupling in an alternating signal being herein called control signal sE(t) (see, FIG. 8).

In order to symbolize the fact that a non-linear circuit element 10 is employed, the circuit symbol of the circuit element 10 is provided with an inclined crossing line in the figures. The circuit symbol has arrows designated with EF, since the non-linear circuit element 10 can be influenced by the external radiation field EF.

In order to be able to accordingly use the non-linear circuit element 10 in an oscillating circuit of the invention, an operation range is determined by using characteristic curves or characteristic fields so that the circuit element 10 can be operated in the non-linear region. It is also possible to empirically determine a point of operation or range. The circuit environment of the apparatus 100 thus has to be designed (dimensioned) accordingly.

Due to the fact that a non-linear circuit element 10 is part of the oscillating system (e.g. having the form of an oscillating circuit) of the invention, the oscillating system is a non-linear oscillating system. The non-linear oscillating system thus can only be described by non-linear network equations.

The non-linear circuit element 10 of the invention preferably comprises a material in which a charge carrier zone can form itself. The charge carrier zones can be inherently present (e.g. by a suitable doping of the material of the circuit element 10 using foreign atoms) and can be influenced by the application of a bias voltage.

In the static state (i.e. if the oscillating system of the apparatus 100 is not operated) differently doped zones are standing opposite to each other, separated by the charge carrier zone and an electric field shown (like in a plate capacitor). This electric field can be modulated by the application of alternating values (e.g. in the form of an alternating voltage) to the non-linear circuit element 10.1.

The charge carrier zone can also be called depletion zone, whereby the effect of the depleting zone will be canceled temporarily or dynamically altered by the modulation of the field inside the material. The modulation of the field might cause a re-diffusion of the charge carriers.

Semiconductor materials are suited as materials for the non-linear circuit elements 10. Isolating materials are not suitable.

It is important that there are charge carriers in the material of the non-linear circuit element 10 which are moveable. Herein, electrons, holes and ions are considered to be charge carriers.

Solar cells and other light sensitive semiconductor circuit elements (diodes, transistors, LEDs, OLEDs, ELDs, opto couplers and so forth) and also combinations of the mentioned light sensitive semiconductor circuit elements are suited as non-linear circuit elements 10. These circuit elements are herein summarized by the term “solar element”.

If a light sensitive circuit element is serving as non-linear circuit element 10 of an apparatus 100, then this is being operated in a range so that there is a non-linear relationship between an input value (e.g. an input voltage) and an output value (e.g. a current).

If the light sensitive circuit element is acted upon by an external radiation field EF, then an electric signal amplification occurs as compared to a conventional DC situation and/or a modification of the field inside the material of the light sensitive circuit element being operated as non-linear circuit element 10 occurs.

Up to this point, the non-linear behavior of light sensitive circuit elements (as mentioned above) is not taken into consideration or not used Especially such circuit elements are not or almost not used in circuits, which are to be acted upon by an alternating signal.

A light sensitive circuit element has a photo-active zone (e.g. in the form of a photo-active layer) inside the (semiconductor)material of the circuit element. So called recombination effects are occurring which are influenceable by the application or coupling in of the external radiation field EF (e.g. light).

The external radiation field EF for instance may have an impact on the modulatable charge carrier transport in the material of the non-linear circuit element 10.

The apparatus 100 of the invention is preferably an analog operating apparatus which preferably can be stimulated continuously by means of an alternating current source G with currents or voltages. However, it is also possible to control the apparatus 100 of the invention with control pulses.

The characteristic frequencies where the non-linearity becomes noticeable preferably is laying in a range from 5 kHz to 10 MHz, and preferably in the range from 6 kHz to 5 MHz for embodiments which comprise a solar cell with doped silicon material. Preferred are frequencies in the range from 7 kHz to 2 MHz.

The required frequencies are considerably higher for light sensitive diodes serving as non-linear circuit elements 10. In embodiments which employ diodes as non-linear circuit element 10, the frequencies preferably are in a range of more than 600 kHz and particularly preferably in a range of more than 1000 kHz.

Thus, in these embodiments, a generator G can be employed which is operating in the respective frequency range.

In FIG. 2, the electric equivalent circuit of a first apparatus of the invention is shown. An electric equivalent circuit here comprises an inductivity L1, a capacity C1 and an ohmic resistor R1. Furthermore, the symbol of the non-linear circuit element 10 is shown. In the embodiment of FIG. 2, this circuit element 10 is arranged in series with the other elements mentioned.

In order to obtain an oscillating circuit suitable for self-oscillation and for taking out energy, the apparatus 100 might comprise a capacity Cb, which is for instance arranged in parallel to the non-linear circuit element 10.

The oscillating circuit of the apparatus 100 can, for instance, be stimulated by an alternating signal source G, as indicated in FIG. 2. The impact influence of the non-linear circuit element 10 on the oscillating circuit influenceable by the external radiation field. In FIG. 2, the external radiation field EF is symbolized by an arrow, as already mentioned.

The electro-magnetic waves of the external radiation field EF can be artificially generated waves (e.g. from a lamp) or naturally occurring waves (e.g. day light).

In the classical sense, the inductivity L1, capacity C1 and the ohmic resistor R1 of the apparatus 100 behave linearly. The differential equations which are describing such a series oscillating circuit with the elements L1, C1 and R1 are linear, too. The non-linearity is achieved by including the non-linear circuit element 10 in the oscillating system and by its specific operation in the non-linear region.

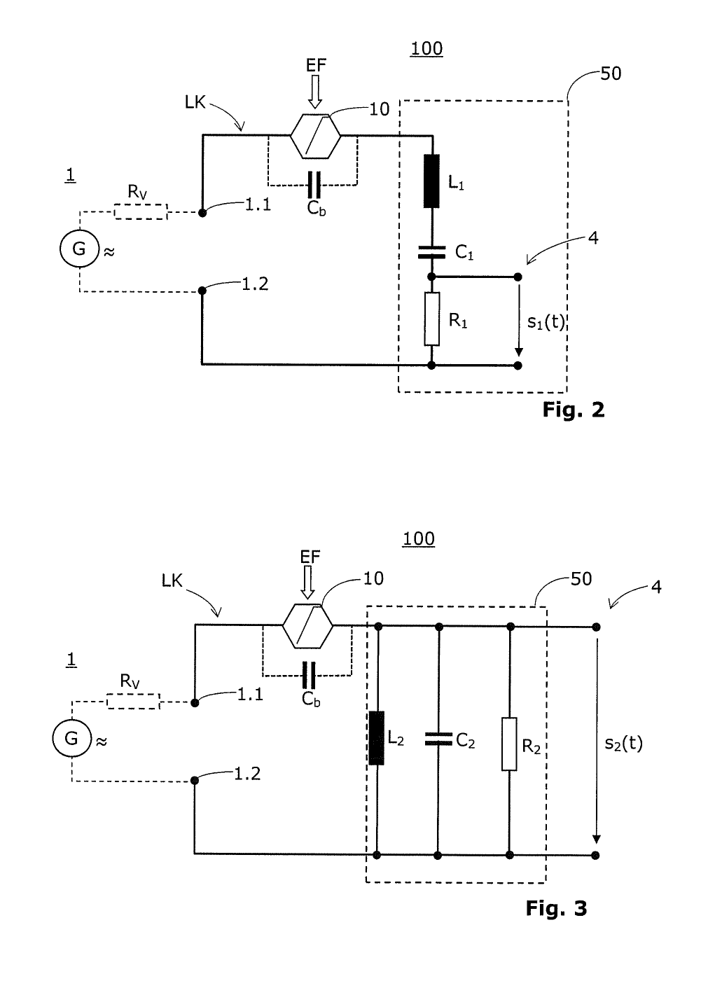

In FIG. 3, the electric equivalent circuit of a second apparatus of the invention is shown. An electric equivalent circuit of a parallel oscillating circuit comprises an inductivity L2, a capacity C2 and an ohmic resistor R2, Furthermore, the symbol of the non-linear circuit element 10 is shown. In the embodiment of FIG. 3, this circuit element 10 is arranged in series with the other elements connected in parallel.

In FIG. 4, the electric equivalent circuit of a third apparatus of the invention is shown. An electric equivalent circuit of a further parallel oscillating circuit is constructed like the apparatus of FIG. 3. A capacity C2 and an ohmic resistor R2 are provided here. The electric equivalent circuit of FIG. 4 further comprises a transformer TR which is supplied by a current I(t) a generator G. The transformer TR provides for a galvanic separation between the control by e generator G and the oscillating circuit. The coil at transformer TR secondary side has an inductivity, which is here designated by L3. Apart from that, the circuit of FIG. 4 is comparable with the circuit of FIG. 3. Furthermore, the symbol of the non-linear circuit element 10 is shown in FIG. 4, In the embodiment of FIG. 4 this circuit element 10 is arranged in series with the elements connected in parallel.

The electric equivalent circuit of FIG. 4 shows a so-called self-propelling structure (also called self-oscillator) in which the control takes place by a pulse sequence (control pulse sequence). Due to the introduction of energy, which is being provided by the external radiation field EF, the oscillation can be maintained or even amplified.

The electric equivalent circuit of FIG. 4 comprises an optional feedback 2 which provides a connection between the output side of the non-linear circuit element 10 and the input side of the transformer TR.

In FIG. 4, preferably an alternating current is used,

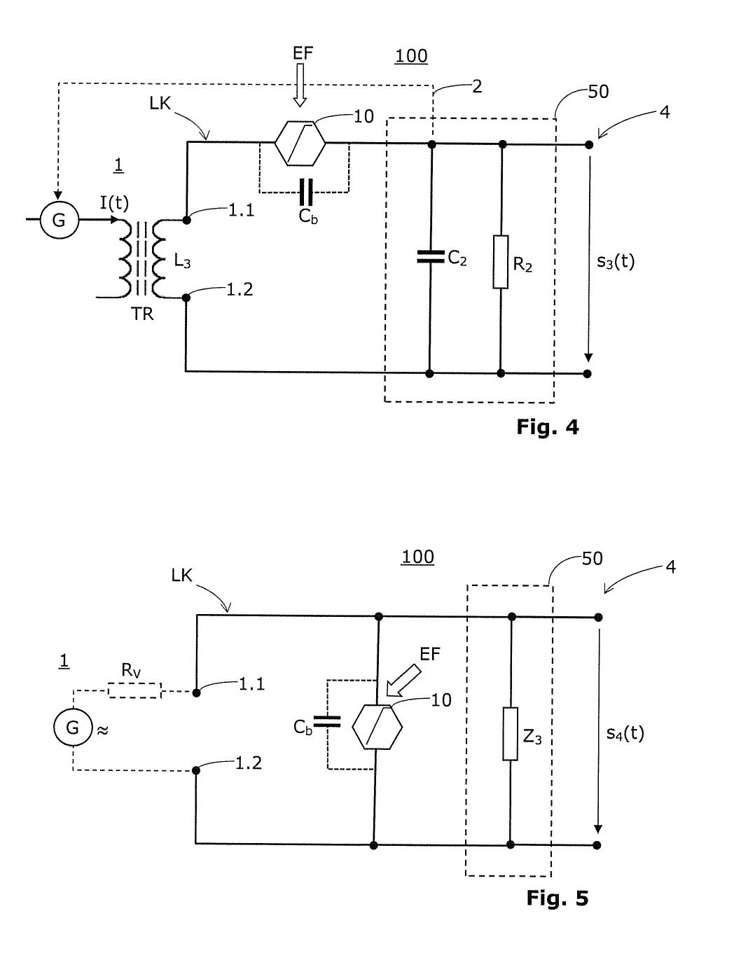

In FIG. 5, the electric equivalent circuit of a further apparatus of the invention is shown. The electric equivalent circuit differs from the other equivalent circuits in that the non-linear circuit element 10 is connected in parallel to an impedance Z3.

Preferably, so-called space charge zones are forming in a solar element 10.1, depending on the structure and constellation. Due to their spatial separation, these space charge zones function like a (space charge-)capacity, as already mentioned.

In the equivalent circuit, the power circuit LK of the invention can be regarded as an interconnection of an inductivity and a capacity. All inductive elements/circuits (such as the inductivity(ies) of the solar element 10.1) of the real circuit elements of the power circuit are combined in this inductivity. All capacitive elements/circuits (such as the capacity(ies) of the solar element 10.1) of the real circuit elements of the power circuit are combined in this capacity. The equivalent circuit furthermore comprises at least one resistive element which, for instance, combines the resistors of supply lines and the path resistors of the p- and n-doped regions of the solar element 10.1.

The power circuit of the invention can form a circuit being able to oscillate because of the inductivity and the capacity which serves as oscillating system.

Preferably, a switching frequency above the lower limiting frequency is employed. Preferably, a switching frequency is employed that is in the already-mentioned range between 5 kHz and 10 MHz. Particularly preferred are frequencies in the range between 6 kHz and 5 MHz, respectively between 7 kHz and 2 MHz. Preferably, this switching frequency is smaller or equal to the self-oscillating frequency of the self-oscillation of the oscillating circuit including the solar element 10.1. Preferably, the switching frequency is an integer multitude of the frequency of the self-oscillating frequency.

The oscillating system can be designed as parallel oscillating circuit (the same voltage is present at the capacity and the inductivity, but the currents are different) or as serial oscillating circuit (the same current is flowing through the capacity and the inductivity, but the voltages can be different).

The various circuits can be translated into each other by conversion or they can be compared with each other.

The difference between serial and parallel oscillating circuits is sufficiently known. In the present description these differences are thus not explicitly addressed.

The invention can be employed in serial oscillating circuits with solar element(s) 10.1 and in parallel oscillating circuits with solar element(s) 10.1.

The non-linear behavior of the non-linear circuit elements 10 and the non-linear influencing of the oscillating circuit cannot be described by means of complete analytic expressions. Thus, the already mentioned characteristic curves or fields are employed in order to illustrate the non-linear behavior of the circuit element 10 in the oscillating circuit.

The signal values which appear in the oscillating system are represented by functions of the time (e.g. S1(t)) because of the time-dependent behavior.

Preferably, the apparatus 100 of the invention comprises the mentioned power circuit LK with at least one solar element 10.1 (which, for instance, might comprise one or more solar cells 3). This power circuit LK is designed in order to be able to provide electric power at a tap 4 if an external field EF (e.g. in the form of light) is applied. The power circuit can be defined by an equivalent circuit diagram (see FIG. 2, 3, 4, 5, 6, 7, 9, 10) which comprises the elements of an electric oscillating system. Furthermore, the power circuit LK might comprise a switchable element 1 (here, in short, called switch) which for instance is switchable from a blocking state into a transition state by means of the control signal sE(t). Furthermore, the apparatus 100 comprises means (e.g. a generator G) for making available the control signal sE(t) that is alternatingly switching the switchable element 1 from the blocking state into the transition state.

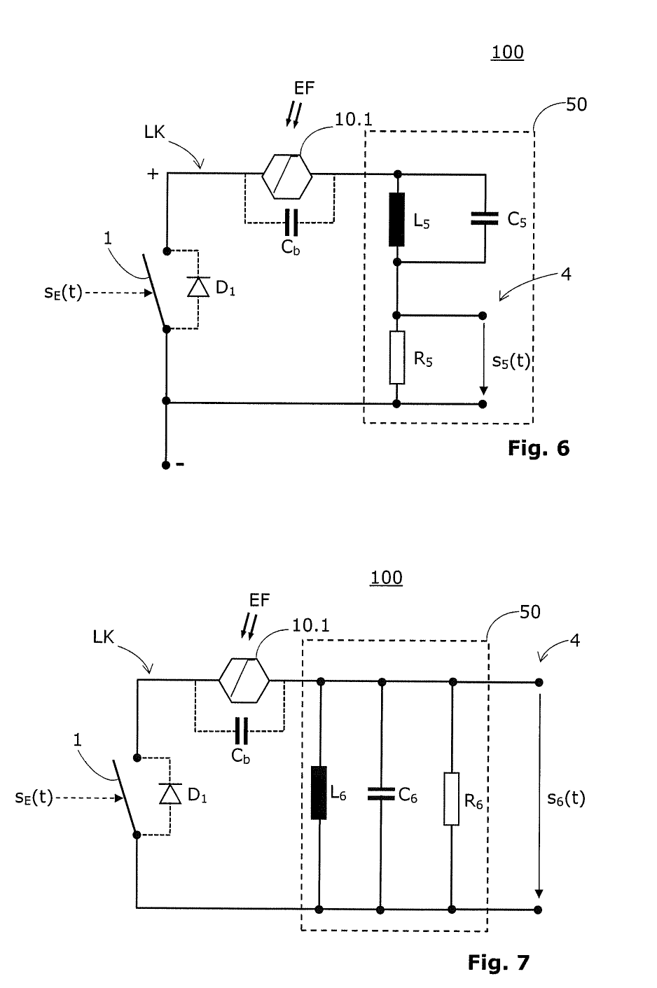

The switchable element 1 might comprise an inner diode (this diode can for instance be part of a transistor) or a diode D1 can be arranged in parallel to the switchable element 1, as depicted in the FIGS. 6 and 7.

In FIG. 6, the electric equivalent circuit of a fifth apparatus 100 of the invention is shown. The electric equivalent circuit of a serial oscillating circuit comprises an inductivity L5, a capacity C5 and an ohmic resistor R5. Furthermore, the symbol of the solar element 10.1 is shown. In the embodiment of FIG. 6, this solar element 10.1 is arranged in series with the other elements mentioned, whereby the inductivity L5 lies parallel to the capacity C5. A so-called power circuit LK is shown in FIG. 6. The power circuit UK concerns the part of the apparatus 100 which is envisaged and designed for providing electric power. It is thus possible to take off an output signal s5(t) at a tap 4.

Preferably, the power circuit LK can draw electric energy directly or indirectly from the solar element 10.1 being illuminated by light.

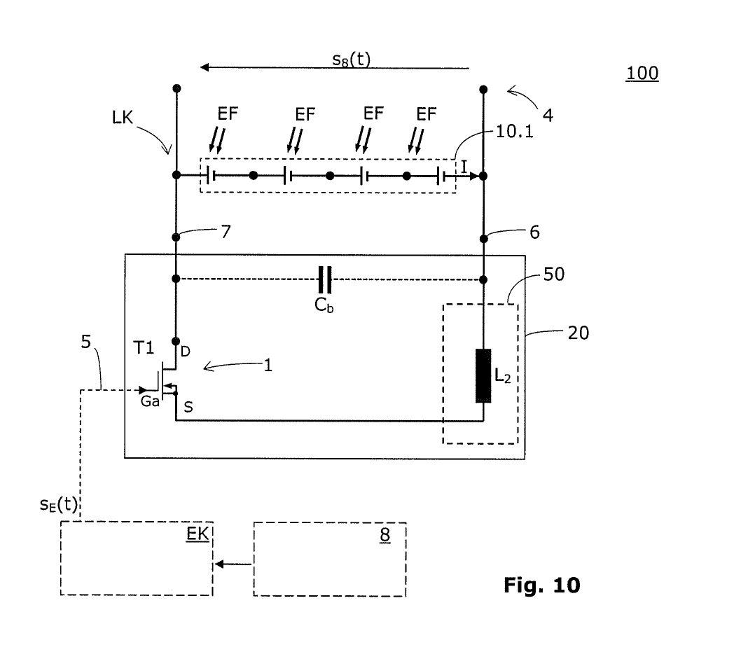

Preferably, the power circuit UK forms an oscillating circuit which can be stimulated by means of the control signal sE(t), as already mentioned. The control signal sE(t) acts, for example, upon the switch 1 (see FIGS. 6 and 7) or upon a transistor T1 (see FIGS. 9 and 10), which can be opened and closed by the control signal sE(t) altematingly.

In FIG. 7, the electric equivalent circuit of a sixth apparatus 100 of the invention is shown. The electric equivalent circuit diagram of a parallel oscillating circuit is here comprising an inductivity L6, a capacity C6 and an ohmic resistor R6. Furthermore, the symbol of the solar element 10.1 is shown. In FIG. 7, the solar element 10.1 is arranged in series with the parallel connected elements L6, C6 and R6. One can take off an output signal s6(t) at the tap 4, for example.

The voltage-time diagram of an exemplary switching signal sE(t) of the invention is shown in FIG. 8. A signal here comprises a sequence of rectangular pulses repeating themselves periodically. The sampling ratio Δ (called duty-cycle in English) is specified in percent as dimensionless number and it can lie between 0% and 100% (in practice 0<Δ<100), The duty-cycle A is temporal ratio of pulse duration over pulse period. The duty-cycle Δ=25% in the example of FIG. 8. In addition to the duty-cycle Δ, the switching signal sE(t) is defined by the amplitude, which is here denoted as UE, and by the frequency f, as is known in for periodic or quasi-periodic signals.

The control of the oscillating circuit can be effected by a periodic or quasi-periodic switching signal sE(t), as is exemplarily illustrated in FIG. 8.

A signal which comprises switching pulses repeating themselves regularly is herein designated as periodic signal. A signal which comprises switching pulses repeating themselves regularly in a shorter time period and which, if observed during a longer time period, can be subject to slight variations (e.g. of the amplitude and/or the frequency of the switching pulses), herein designated as quasi-periodic signal. Such a variation of the control signal might for instance occur in situations in which the apparatus 100 includes a control circuit EK (see FIG. 10, for example), which is reacting on changing environmental conditions (e.g. on a declining incident solar radiation).

In order to supply a control circuit EK or a generator G with energy, a connectable or connected electric energy source (here referred to as energy supply 8) might be employed. This is exemplarily illustrated in FIG. 10.

A power supply (which is for example fed with grid voltage), an accumulator or a supercap can serve as connectable energy supply 8, for example. The connectable electric energy supply 8 might comprise one or more of these elements or a combination or two or more different elements.

FIG. 9 shows the connection scheme of a further embodiment of an apparatus 100 which is based on the principle of the equivalent circuit of the FIG. 7, A serial arrangement of a solar element 10.1 is concerned which here comprises a serial circuit of four solar cells with an inductivity L7. A tap 4 is here exemplarily provided across the inductivity L7. A MOSFET T1 is employed as switch 1, as illustrated. MOSFET is standing for “metal oxide semiconductor field effect transistor” In order to make possible an easier mapping, the gate at this MOSFET T1 is designated with Ga, the source with S and the drain with D. This embodiment, to be concrete, concerns a n-type enhancement mode MOSFET. The channel of the MOSFET T1 is activated by the application of a control signal sE(t) at the gate Ga by inducing charge carriers between source S and drain D into the region underneath the gate Ga. Thereby, the channel of the MOSFET T1 is switched through (conductive) if a positive voltage is applied to the gate Ga. If one uses, for example, the stimulating signal sE(t) of FIG. 8, then the MOSFET T1 provides a conductive connection between source S and drain D if a positive voltage is applied. If, however, no voltage is applied between two pulses (pulse pause) then the connection between source S and drain D is interrupted (that is the switch 1 is open).

The FIG. 10 shows the block diagram of a further embodiment being based on the principle of FIG. 9. The description of the FIG. 9 is thus applicable. Only the differences are addressed here. The essential elements (except for the solar element 10.1) are concentrated in FIG. 10 so that they can be contained in some kind of a control gear 20. This control gear 20 might for example have two contacts 6, 7 (e,g. in the form of clamps) making it possible to electrically connect the control gear 20 in parallel with the solar element 10.1. The tap 4 is for example arranged in parallel to the solar element 10.1, However, it can also be provided at another point making it possible to draw electric power out of the apparatus 100 if the solar element 10.1 is lit with light.

The switch (here again realized as MOSFET T1) can be switched by a control signal sE(t), as already mentioned. In case of the embodiments of FIG. 9, 10 the control signal sE(t) can be externally supplied or it be provided inside the control gear 20 and/or by means of a control circuit EK and/or by the solar element 10.1.

The control signal sE(t) can for example be provided via a communication line or via a communication network. This way, the control signal sE(t) can, for example, be handed over from a center (e.g. by a network operator or a net agency) to the switch 1.

For example, in order to make the apparatus self-sufficient, the control signal sE(t) can be provided within the control gear 20 and/or the control circuit EK and/or by the solar element 10.1.

If one now looks at the real solar element 10.1 of the various embodiments in the overall context of the power circuit LK, it becomes obvious that the power circuit LK forms an electric oscillating system (preferably an electric oscillating circuit) which comprises the capacities (e.g. Ca) of the solar cells 3 (see FIG. 1B) and the inductivity (e.g. L7).

In order to operate the apparatus 100 of the invention oscillatingly, the switch 1 can for example be alternatingly (periodically or quasi periodically) opened and closed again, which can be achieved in the respective embodiments, for example, by the application of a suitable control signal sE(t) with suitable switching frequency. Now the charging and de-charging of the capacity(ies) takes place, as is common for an oscillating circuit. That is, charge carriers are temporarily stored. And it comes to an energy buffering in the magnetic field of the inductivity of the oscillating circuit (e.g. L7). This results in the self-oscillating behavior of the oscillating circuit. A signal can, for example, be taken out as output signal (e.g. s7(t)) which comprises a direct portion and/or an alternating portion.

Preferably, electric power (e.g. at the tap 4) is drawn out of the oscillating circuit when the switch 1 is open (i.e. during the pulse pauses of the control signal sE(t) of FIG. 8).

Since the power circuit LK is showing an oscillating behavior, not only the photo electrons (as is normal for solar elements 10.1) but also electric and mechanic oscillations are made useable. In the conventional direct current operation of solar elements 10.1, these oscillations are transformed into pure heat losses.

In addition to the power circuit LK, details of an exemplary control circuit EK are shown in FIG. 10. This control circuit EK might be designed for example for providing the required control signal sE(t), as is illustrated in FIG. 10 by a circuit block. For this purpose, the control circuit EK might comprise a frequency generator so as to generate the control signal sE(t).

Such a control circuit EK can also be employed in connection with other embodiments of the invention.

In order to trigger and maintain the self-oscillating behavior of the apparatus 100, an apparatus for internal generation of the control signal sE(t) can, for example, monitor the course of the output voltage (e.g. s2(t)) and/or the current I, in order to generate or trigger a switching pulse of the switching signal sE(t) if certain requirements are reached.

In an exemplary embodiment, the temporal change of the output voltage (e.g. δs2(t)/δt) and/or the current (e.g. δI(t)/δt) are evaluated for providing the control signal sE(t). This can, for example, be achieved by a separate or integrated circuit.

The non-linear response s1(t), s2(t) or s3(t) (also called output signal) of the oscillating circuit of the apparatus 100 can, for example, be taken off at the resistor R1, as schematically depicted in FIG. 1, or at the resistor R2, as schematically depicted in FIGS. 2 and 3, or at the impedance Z3, as schematically depicted in FIG. 4.

The tapping of an output signal or an output value can also be done at another point of the apparatus 100.

Preferably, an output signal or an output value is taken off at the apparatus 100 so that the oscillating behavior is not or only marginally disturbed. A tap 4 is probably provided which is geared towards (adapted to) the overall circuit.

The tap 4 (respectively the tap points) also can be at other positions of the apparatus 100. This is dependent on whether one wants to couple out current or voltage in direct or alternating form and to which extent the coupling out of electric power influences the oscillating behavior of the oscillating system.

The alternating signal generator G, if present, is generating an external stimulation of the oscillating system of the apparatus 100.

Preferably, the alternating signal generator G, if present, designed as a current source in order not to load the oscillating system of the apparatus 100. Thus, a series resistor RV is shown in FIGS. 2 and 3 in order to decouple the generator G from the oscillating circuit. The application of such a series resistor RV is optional. In the figures, the series resistor RV is thus dashed.

Depending on the embodiment of the invention, the non-linear circuit element 10 can comprise a non-linear capacity and/or a non-linear inductivity. Due to this, a non-linear term in introduced into the oscillating circuit of the apparatus 100.

If the non-linear circuit element 10 comprises a capacity, then the apparatus 100 does not necessarily have to have a further capacity in the oscillating system for the operation of the apparatus 100. If the non-linear circuit element 10 comprises for example an inductivity, then the apparatus 100 does not necessarily have to have a further inductivity in the oscillating system for the operation of the apparatus 100.

The equivalent circuit diagrams of FIGS. 2, 3, 4, 5, 6, 7, 9, and 10 are to be understood so that all capacities are concentrated into one capacity (e.g. C1 respectively C2). This also includes a possible capacity of the non-linear circuit element 10 and of the conductive path or the cable of the oscillating circuit. Respectively, all inductivities are also concentrated into the one inductivity (e.g. L1 respectively L2) and all resistors into one resistor (e.g. R1 respectively R2).

The non-linear capacity of the non-linear circuit element 10 can, for example, occur due to charge fronts which have developed in the material of the circuit element 10 (e.g. during the production) or which develop (e.g. when initializing or during operation of the oscillating circuit). In this way, positive and negative charges can face each other in a semiconductor diode, for example.

In order to continuously operate an apparatus 100 of the invention, an adjustment of the control signal (it can here be applied to the points 1.1, 1.2, for example) is preferably carried out with the characteristic of the oscillating circuit comprising the non-linear element 10. For this, characteristic curves or characteristic fields can be determined and from these suitable operation points or operation ranges can be derived. Subsequentially, the apparatus 100 can then be operated in the operation point or operation range by the specification of respective input-side control signals or values.

For this purpose, preferably the voltage, the frequency and/or the signal shape of the generator G, if present, are specified accordingly.

The non-linear behavior of the non-linear circuit element 10 preferably develops due to the superposition or the interaction of an inherent non-linear material property of the non-linear circuit element 10 as such with the external radiation field EF (e.g. in the form of light).

If not mentioned otherwise, all features of the present invention can be combined freely with each other. The features described in the description of the figures, if nothing else is indicated, are features of the invention that can be combined freely with the other features, also specified in the claims.

### REFERENCE SIGNS

switchable element 1
taps/points 1.1, 1.2
feedback 2
Solar cell 3
tap 4
Stimulating line 5
contacts 6, 7
Energy supply 8
non-linear circuit element 10
Solar element as non-linear circuit element 10.1
control gear 20
arrangement 50
apparatus 100
Capacity C
Capacity Cₐ
Capacity C_{b}
Capacity Cₙₗ
Capacity C₁
Capacity C₂
Capacity C₅
Capacity C₆
Diode Da
Diode Di
Diode D1
Duty cycle Δ
temporal change of the output voltage δs₂(t)/δt
temporal change of the current δI(t)/δt
external radiation field EF
Frequency f
Alternating signal source/generator G
current I
current I(t)
Saturation current Iₛ
Photo current Iₚₕ
Inductivity L
Inductivity L_{D}
Inductivity Lₚₕ
Inductivity L₁
Inductivity L₂
Inductivity L₃
Inductivity L₅
Inductivity L₆
Inductivity L₇
Load LA
Power circuit LK
Side of the n-doped layer of the solar element n
Side of the p-doped layer of the solar element p
Charge carrier density q
Resistor R
Resistor Rₙₗ
Resistor R₁
Resistor R₂
Resistor R₅
Resistor R₆
Parallel resistor R_{SH}
Series resistor R_{SE}
series resistor R_{V}
Switching signal S_{E}(t)
Output voltage s1(t), s2(t), s3(t), s4(t), s5(t), s6(t), s7(t)
time t
Transistor/switching element T1
Transformer TR
Voltage U
Amplitude U_{E}
complex-valued impedance Z
impedance Z₃

What is claimed is:

1. An apparatus comprising:
an oscillating circuit with a non-linear circuit element wherein the non-linear circuit element is operable in a non-linear operating range and with a frequency above a limiting frequency.

2. The apparatus according to claim 1, wherein the oscillating circuit comprises at least one complex-valued impedance.

3. The apparatus according to claim 2, wherein the complex-valued impedance or at least one inductivity or one capacity of the impedance is part of the non-linear circuit element.

4. The apparatus according to claim 1 wherein the oscillating circuit at the input side can be stimulated by an alternating signal source so that the non-linear circuit element is operable in a pre-determined non-linear operating range.

5. The apparatus according to claim 2 wherein the complex-valued impedance comprises at least one capacity and/or inductivity.

6. The apparatus according to claim 1 wherein the non-linear circuit element comprises a material having one or more space charge zones which, when operated, are influenceable with an alternating voltage or an alternating current.

7. The apparatus according to claim 1 wherein the non-linear circuit element comprises one or more of the following materials:
semiconductor material;
photo-electro-chemically active material.

8. The apparatus according to claim 1 wherein the non-linear circuit element has an internal structure comprising two different material regions or material layers and one material transition between these two different material regions or layers.

9. The apparatus according to claim 8 wherein the two different material regions each comprise differently doped semiconductor materials.

10. The apparatus according to claim 1 wherein the non-linear circuit element is a solar element.

11. The apparatus according to claim 1, wherein the oscillating circuit is designed a self-oscillator.

12. The apparatus according to claim 1 wherein the apparatus represents a self-oscillating structure which is excitable by means of periodic or quasi-periodic switching signals.

13. The apparatus according to claim 1 wherein the non-linear circuit element is designed so that it is influenceable by an external radiation field.

14. The apparatus according to claim 1 wherein the non-linear behavior of the non-linear circuit element arises because of a superimposition of an inherent non-linear material property of the non-linear circuit element with an external radiation field.

15. An apparatus with an electrical oscillating system comprising a solar element as a non-linear circuit element and at least one further circuit element to excite the solar element permanently or periodically into an oscillation with a frequency above a lower limiting frequency while the solar element is exposed to an external radiation field (EF) in the form of light.

16. The apparatus of claim 15 wherein the external radiation field (EF) is an electric or magnetic or electro-magnetic field.

17. The apparatus of claim 15 further comprising an ohmic resistor.

18. The apparatus of claim 15 wherein by operation of the non-linear circuit element in the oscillating circuit, spatial and/or time alterations of the electric field in the material occur.

19. The apparatus of claim 18 wherein the material of the non-linear circuit element includes a charge depleted zone.

20. A method for operating an apparatus in an artificially generated or naturally occurring radiation field comprising: exciting an oscillating system by means of an alternating signal source or a control signal, whereby the oscillating system comprises a solar element as a non-linear circuit element:
introducing or exposing the solar element into the radiation field;
exciting an oscillation behavior of the oscillating system, including the solar element, by means of the alternating signal source or the control signal, whereby the solar element is operated in a non-linear operation region with a frequency above a lower fundamental frequency;
making available an alternating current signal and/or a direct current signal to at least one tap of the non-linear circuit element.

21. The method according to claim 20, wherein the radiation field is ii

22. The method according to claim 20, wherein the frequency at which the oscillating system is being operated is in the range between 5 kHz and 10 MHz.
